(19) United States
(12) Patent Application Publication
(10) Pub. No.: US 2007/0275264 A1
(43) Pub. Date: Nov. 29, 2007

(54) Stainless Steel Strip Coated With A Decorative Layer

(76) Inventors: Anna Stigenberg Hultin, Sandviken (SE); Mikael Schuisky, Sandviken (SE); Ulrika Isaksson, Sandviken (SE); Mats Ahlgren, Taby (SE)

Correspondence Address: DRINKER BIDDLE & REATH (DC), 1500 K STREET, N.W., SUITE 1100, WASHINGTON, DC, 20005-1209, US

(21) Appl. No.: 10/584,079

(22) PCT Filed: Dec. 15, 2004
(86) PCT No.: PCT/SE04/01870

§ 371 Date: May 4, 2007

(30) Foreign Application Priority Data
Dec. 23, 2003 (SE) 0303596-1

(51) Int. Cl. B32B 33/00; C23C 14/06; C23C 14/08; C23C 14/22

(52) U.S. Cl. 428/687; 204/192.1

(57) ABSTRACT

The invention relates to a coated stainless steel strip product with an evenly distributed layer on one side or both sides of said strip. Said layer has a decorative appearance, the thickness of said layer is maximally 10 μm, the tolerance of said layer is maximally +/−30% of the layer thickness, the parameter value of L*, a*, b* is respectively 0<L*<95, −66<a*<64, −90<b*<70, the tolerance of said decorative appearance as expressed in terms of ΔE is maximally 15 and the layer has such a good adhesion so that the coated steel strip when tested in soft-annealed condition can be bent more than 90° over a radius maximally equal to 5*t, where t is the thickness of said strip, without showing any tendency to flaking or the like.

The present invention relates to a new coated stainless steel strip material with a covering layer with a decorative surface finish. It also relates to a method of manufacturing such a coated steel strip in a continuous roll-to-roll process, which results in a very good adhesion of a decorative covering layer on a metal strip substrate. In particular, it relates to coated steel strips with good formability and with such a good adhesion of the decorative layer that they are suitable for use in consumer related applications, although many other uses also are feasible.

### BACKGROUND TO THE INVENTION AND PRIOR ART

It is known that decorative coatings can give an attractive surface finish to consumer related products. However, for components in smaller dimensions, which are to be produced in a cost-efficient and productive way, there are difficulties in finding a method that can attain the quality and productivity requirements. For productivity reasons, a roll-to-roll coating process is imperative, and for quality reasons, a thin layer with excellent adhesion is needed.

The superior adhesion is required for the functional quality of the final product, but also to enable a cost-efficient and productive manufacturing of components. Thus, a coated strip material with inferior adhesion would cause problems with, e.g., flaking, and this would result in a low yield and also in a disturbance caused by the flakes themselves of the manufacturing process as such, especially if the manufacturing process is in a continuous line. Moreover, more frequent stops would be needed for quality inspections and for cleaning the process line from flakes. All in all, poor adhesion of the coating would result in a non-acceptable high manufacturing cost and low quality.

There are several common methods of making a decorative surface finish on metallic materials. As examples can be mentioned:
Anodizing is a known method that can be used for various colours. Normally this method is used on aluminum or aluminum alloys. An obvious drawback is that it is not possible to use directly on stainless steels.
Vapor deposition methods are used in some cases for colouring of metallic products. Often the colour is produced by applying a metal nitride to the surface of the component. However, most methods are batch-like processes, which mean that the coating is done on the finished component piece by piece. One obvious drawback with such a method is that it is not continuous, and thus also very expensive to use. Examples of batch coating on consumer related products are revealed in U.S. Pat. No. 6,197,438 B1, U.S. Pat. No. 5,510,012, and EP-A-1 033 416.
Recent developments in PVD technology has led to the manufacturing of continuous PVD coating lines for various reasons, so called web-coaters are commonly used to coat plastic foils for food packing i.e. chips bags etc. Continuous PVD lines are also used for the manufacturing of highly reflective surfaces on aluminum strips, semi-continuous PVD lines are also commonly used to coat window glass. Less common are continuous PVD lines for coating stainless steel materials with functional layers. In U.S. Pat. No. 6,197,132 a continuous PVD line for coating stainless steel strip with aluminum is described. Also in the article “Innovative steel strip coatings by means of PVD in a continuous pilot line: process technology and coating development” by B. Schuhmacher et al., Surface and Technology 163-164, (2003) pp 703-709, a continuous PVD process for depositing Zn-alloys as corrosion protection. Furthermore, in U.S. Pat. No. 4,763,601 a continuous line for coating of steel strip is described. In said coating line several different coating zones are integrated, including ion plating, sputtering and plasma CVD. However, the strip speeds used in U.S. Pat. No. 4,763,601 would render a very low productivity. Moreover, the low feed speed of the belt causes long presence times in the coating zones which could result in a deteriorated end product.
One commonly used method is painting of the metallic surface with coloured lacquers, or the like. However, in most painting processes the painting is done on the finished component piece by piece. One obvious drawback with such a method is that it is not a continuous roll-to-roll process, and thus also quite expensive to use. A continuous painting process is normally not possible to use since the adhesion usually is not good enough for further processing in, e.g., forming operations without causing defects or flaking in the surface. Also, paints can normally not withstand further heat treatments.

Thus, the methods as described in the examples above cannot be used for the present invention.

Therefore, it is a primary object of the present invention to provide a decorative coated metal strip with good adhesion between the decorative coating and the substrate.

A further object of the present invention is to obtain a cost-efficient decorative coating in a continuous roll-to-roll process with a minimum strip speed of 3 m/min, integrated in the production of a stainless steel strip.

Yet another object of the present invention is to provide a coated stainless steel strip product with a decorative coating in combination with good formability, so as to enable the manufacturing of consumer related applications of said material.

Furthermore, an object of the present invention is to provide a coated stainless steel strip with a decorative layer that if desired can be heat-treated in a tempering or hardening process without changing its colour.

Still another object of the present invention is to provide a method to manufacture a surface finish in connection to a continuous coating in a roll-to-roll process included in a strip production line, which in the further processing by a suitable heat-treatment, can be transformed to a decorative coating.

A further object of the present invention is to obtain a coating with a thickness as uniform as possible.

These and other objects have been attained by providing a coated steel product according to claim 1. Further preferred embodiments are defined in the dependent claims.

### BRIEF DESCRIPTION OF THE INVENTION

The present invention relates to a method of manufacturing coated stainless steel in a continuous roll-to-roll process, which results in an excellent adhesion of a thin covering decorative layer. The decorative layer can as an example be achieved by applying a coating so as a colour appears. The coated stainless steel strips must have such a good adhesion of the thin layer that it is suitable for a cost-efficient and productive manufacturing of components in consumer related applications. The final product, in the form of a decorative stainless strip material, is suitable for use as a decorative component in consumer-related applications that are occasionally used also in environments with high humidity or in conditions requiring a good corrosion resistance.

The decorative layer is deposited by means of Physical Vapor Deposition (PVD) in a roll-to-roll process, to an evenly distributed layer with a thickness of preferably less than 10 μm. The preferred PVD methods to be used are either electron beam evaporation (EB) or sputtering and well known to the skilled man.

The substrate material can preferably be a stainless steel with a Cr content above 10% (by weight) and with a strip thickness of usually less than 3 mm. As a first step, the roll-to-roll process may also include an etch chamber, in order to remove the native oxide layer that otherwise normally is present on a stainless steel.

As an alternative, the decorative surface finish may also be produced in a two-step process, in which first a suitable coating is applied to the stainless steel strip material in a condition allowing good formability, using a method as described above, and thereafter in a subsequent processing of the already coated material, use a suitable heat-treatment, in which the thin coated layer transforms to a decorative surface finish.

### BRIEF DESCRIPTION OF THE DRAWINGS

FIG. 1 shows an illustration of a test specimen in accordance with the present invention, i.e. a coated stainless steel strip with a decorative layer with good adhesion before a test of said adhesion in a bend test over a radius maximally equal to 5*t, where t is the thickness of said strip.

FIG. 2 shows an illustration of a test specimen in accordance with the present invention, i.e. a coated stainless steel strip with a thin decorative layer with good adhesion, and after a bending in an angle of 180°, in a bend test as described in FIG. 1.

FIG. 3 shows schematically an electron beam evaporation production line for the manufacturing of a coated metal strip material according to the invention.

FIG. 4 shows schematically a sputtering production line for the manufacturing of a coated metal strip material according to the invention.

FIG. 5 shows an illustration of the CIE lab ordinates L*, a* and b* values, in which the L* value is the brightness from black to white, the a* value goes from green to red and the b* value is blue to yellow.

### DETAILED DESCRIPTION OF THE INVENTION

### Description of the Coating and the Use of the Invention

The final product, in the form of a coated strip material, is suitable to be used as a decorative component in consumer-related applications such as outdoor life applications, sports and sea-life applications, household applications, camera applications, mobile phones and other telecom applications, edge applications such as knife, saw and shaving applications or the like, and applications for personal belongings and care such as watches, glasses, cosmetic applications, buttons and zippers in clothing, perfume bottles or the like. In principle, these are all applications that preferably can be given an attractive surface finish that by being decorative gives an added design value to the final product. Also, they are occasionally used in environments with high humidity or in conditions requiring good corrosion resistance. At the same time, these types of applications are often expected to be nice-looking throughout its product lifetime, with a shiny appearance, or just a “high quality” appearance. Dull surfaces, with spots or even rust, are normally not acceptable.

Both one-sided and two-sided coatings may be used, but since the component normally is used in the final consumer related product in such a way that only one side is visible, i.e., the external surface, it is preferable from a cost perspective to use one-sided coatings whenever possible. A substrate material in stainless steel also makes this possible, since the coating does not have to act as a corrosion protection in itself, and thus from a corrosion point of view, it does not have to cover the component on all sides.

The method described in the present invention is especially suitable for thin coatings in thicknesses on each side up to 10 μm in total, normally up to 7 μm in total, preferably up to 5μm in total, or at the best maximum 3 μm, or even maximum 2 μm in total, is preferable from a cost perspective. If thicker layers are to be coated, an optimum in cost versus properties may be achieved by using multi-layers with up to 10 layers, and where each layer is between 0,01 to 10 μm thick, suitably between 0,01 to 5 μm, preferably 0,01 to 3 μm and even more preferably 0,005 to 2 μm.

The thickness tolerances obtained by PVD techniques are usually very good. Thus, the tolerances of each layer may be maximally +/−30% of the layer thickness in strip widths up to 400 mm, normally +/−20%, and preferably +/−10%, most preferably +/−7%. This means that very tight tolerances can be achieved, which is of benefit for the precision during usage and the quality of the product. A tight tolerance in layer thickness is also of advantage for achieving a consistency in colour. Thus, thanks to the high coating thickness tolerances, a superior colour consistency has been achieved, even on long belts, such as 5 km and even longer. These long belts have been made possible thanks to the relatively high feed velocities. Colour differences expressed as ΔE (see definition further down) of less than 10 have been achieved for those long belts. For shorter belts, such as up to 100 m ΔE may even be less than 5.

Moreover, thanks to the fact that the belt may be cooled by special cooling means at the same time as it is coated, the cooling taking place on the side of the belt opposed to the side being coated, the heat influence on the belt is largely controlled, so that the properties of the substrate are substantially maintained.

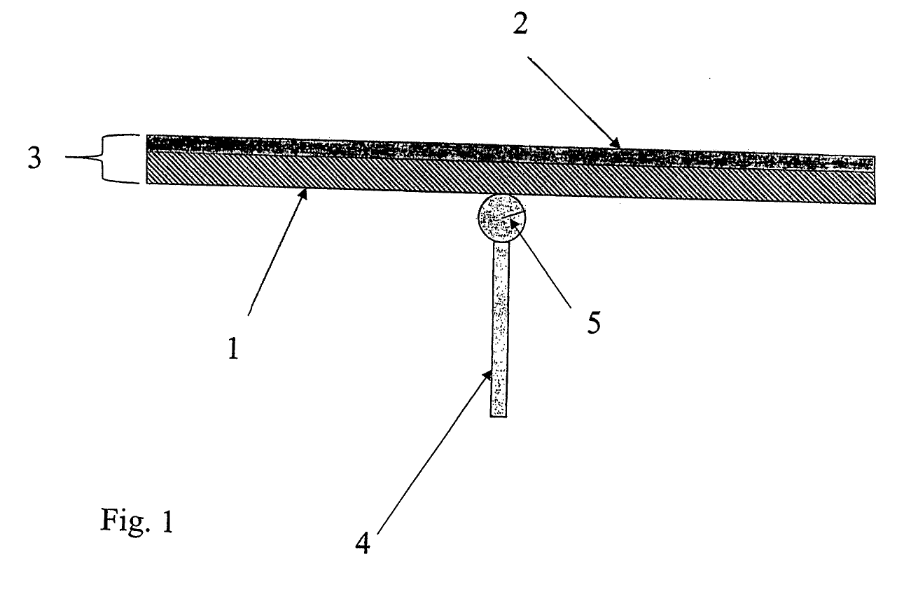

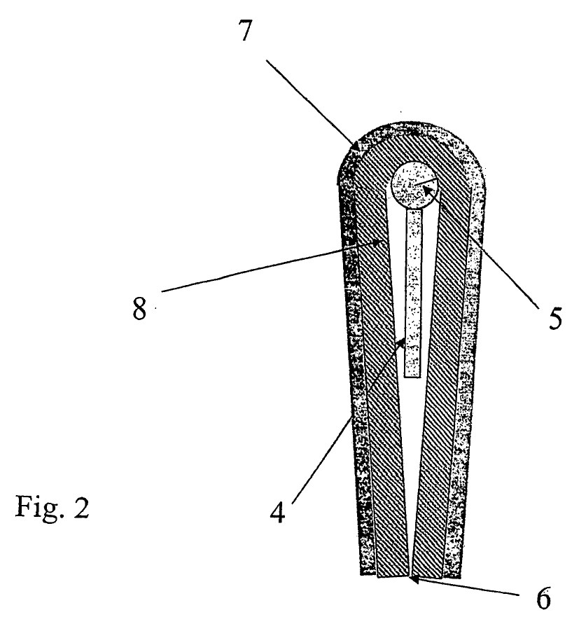

The thin covering layer must have a good adhesion in order for the coated strip product to have a good formability during manufacturing to various components, not to cause problems due to flaking of the layer or the like. The thin layer must also have a good adhesion with regard to the applications and their uses. During usage it is not acceptable that the decorative layer starts to flake off. An illustration of the good adhesion is that with the substrate material in a soft annealed condition, the coated stainless steel strip according to the present invention should be able to be bent a certain minimum angle over a radius maximally 5*t, where t is the thickness of said strip, without showing any tendency to flaking or the like. The minimum angle in this type of bending is typically minimum 90°, normally minimum 120°, preferably minimum 150° and even more preferably 180° (See FIG. 1-2). According to one embodiment of the invention the coated strip should be able to be bent at least 90°, preferably at least 180°, over a radius that is equal to the thickness of the strip without showing any tendency to flaking or the like.

The coated layer should be sufficiently wear-resistant in order to withstand the wear and shear exerted by the treated material, on the other hand it should not be too thick, due to economical reasons and fragility/brittleness. For consumer related applications, the ratio between the thickness of the coating and the substrate material should be between 0,001% to 7%, normally 0,001 to 5% and usually 0,001 to 4%, but most preferably between 0,001-3%.

The decorative appearance can be achieved by depositing several different compounds or elements. Metal oxides are well known to have a decorative appearance and a suitable decorative coating according to the present invention is to use coatings of binary metal oxides such as SiO₂, SiO, TiO, VO, VO₂, TiO₂, Al₂O₃, Cr₂O₃, CoO, NiO, Cu₂O, CuO and as well as coatings of ternary metal oxides such as BaTiO₃, PbCrO₄, Pb₂CrO₅, NaWO₃, NaWO₂, MgAl₂O₄, TiMg₂O₄, LaCrO₃ are decorative. In addition solid solutions and/or mixtures of metal oxides can also be deposited to achieve decorative coatings on the strip substrates. These mixtures or solutions of metal oxides are preferably, Al₂O₃, TiO₂ or Cr₂O₃ based systems. A ternary metal compound such as a ternary oxide can be deposited by means of co-evaporation or by sputtering.

In variation to the above described coatings, also deposited layers of metal nitrides such as TiN, ZrN, CrN, TiAlN are all good examples of a good way to achieve decorative coatings. Also metal carbides and metal carbonitrides such as TiC, TiCN are coatings, which have a decorative appearance. By using this type of coating, the coated strip material can, if desired, be subsequently heat-treated in a suitable gas atmosphere of normally for metal nitrides a nitrogen containing gas, such as N₂, NH₃, N₂H₄ or mixtures thereof, or for metal carbides a carbon containing atmosphere such as CH₄, CH₃CH₃, C₂H₄, C₂H₂ or mixtures thereof, or for metal carbonitrides a gas consisting of a mixture of nitrogen containing and carbon containing gases. The decorative layer can after such a heat-treatment keep its colour achieved in the coating as expressed in terms of L*,a*,b*-values, in a way that the difference in decorative appearance, or colour, between the layer before the heat-treatment and after the heat-treatment as expressed in terms of ΔE, is in strip widths up to 400 mm maximally 15, usually maximally 12, normally 8, preferably 5 and even more preferably 3, and at the best even 1.

This type of coating is therefore of special interest to use for consumer related applications requiring also a high mechanical strength, such as edge applications, e g knife applications, saw applications or shaving applications such as a razor blade, or other high-strength applications, e g out-door applications, glasses or perfume bottles. This is all applications typically manufactured in materials such as hardenable chromium steels, precipitation hardenable stainless steels or cold-rolled stainless spring steels, which normally are heat-treated in a tempering process effected at temperatures in the range 325-525° C., and preferably in between 375-500° C., or in a hardening done at high temperatures, usually above 400° C., normally above 800° C. and in some cases above 950° C. After such a heat-treatment as described here, the substrate material increases its mechanical (tensile) strength to usually above 1000 MPa, typically above 1200 MPa and normally above 1400 MPa, and preferably even above 1500 MPa. This heat-treatment can be performed on the coated strip material in a continuous roll-to-roll process, or on components manufactured from the coated strip product. In the latter case the second step, e g the heat-treatment, is done as a piece by piece process.

Multi-layers may also be used in order to enable a combination of oxides and/or nitrides or carbides, so as to optimize colour spectra, reflectiveness and consisistency in colour by having up to 10 layers with different oxides and/or nitrides or carbides in the layers.

There is normally no need for any separate interlayer bond-coat, but it may still be used in at least one of the layers if it is required from a technical perspective, e.g., to enhance toughness. A suitable bond-coat to use is a pure metal such as nickel, aluminum, chromium, titanium or the like. Since a separate metallic bond-coat layer means an extra cost it is usually used in very thin layers only, suitably between 0 to 2 μm, preferably between 0-1 μm and most preferably between 0-0,5 μm. The interlayer bond-coat may also be used in between the substrate material and the first layer of decorative coating, especially if the first layer is made of a non-metallic coating.

An alternative method to the above described, is to use a two-step method to produce the decorative surface finish. In the first step a suitable coating is applied to the steel strip material using a method as described in the present invention. In this case a suitable coating is a covering layer of a metal such as aluminum, chromium, titanium, zirconium, vanadium, hafnium, copper, nickel, cobalt or a binary oxide of said metals such as Al₂O₃, Cr₂O₃, but it can also be mixtures of these metals and their corresponding metal oxides. In this case a specific thickness and composition of the coating is the most important in the first step, and not the colour itself. The coated steel product should in this stage also be of good formability and have a good adhesion of the substrate and the thin layer, so as to be able to be manufactured in various forming processes as described in the present invention, and as illustrated by the bend-test as described in FIG. 1-2. In a subsequent processing by a selected chemical treatment and/or heat-treatment, the layer can be transformed in composition so that a desired colour is formed on the surface of the material. Preferably, this subsequent treatment is made in connection to an ordinary process, such as during a tempering treatment of a cold rolled spring steel or a precipitation hardenable steel or during a hardening operation of a hardenable chromium steel, or the like. Tempering treatments as described above may be utilised. By selecting an atmosphere in the furnace to be reactive with regard to the coating, the desired transformation of the coating can be achieved.

If it is desirable to have on the final coated strip an oxide coating, then the coated metal layer and/or binary oxide is heat treated in an oxidizing atmosphere, the oxidizing atmosphere can be water vapor, pure oxygen gas, O₂, or different mixtures of oxygen with an inert gas such as Ar, N₂, He, or at the best air at a suitable temperature.

If the desired is to incorporate nitrogen into the metal and/or metal oxide coating, then a reactive gas containing nitrogen may be used during the heat-treatment, including gases such as N₂, NH₃, N₂H₄ or mixed gases of N₂/H₂. The final decorative layer is after such a heat treatment transformed into either a metal nitride or a metal oxynitride.

If the desired is to incorporate carbon into the metal and/or metal oxide coating, then a reactive gas containing carbon may be used as reactive atmosphere during the heat-treatment that will include gases such as CH₄, CH₃CH₃, C₂H₄, C₂H₂ or mixed gases of these. If the final decorative layer should be metal carbo-nitride, the carbon containing gases are mixed with nitrogen containing gases and heat-treated at elevated temperatures.

By using this type of two-step process, an additive element such as oxygen, nitrogen, carbon have been incorporated into the as-deposited layer transforming it into a metal oxide, metal nitride, metal carbide or a mixed type of layer, usually in the form of an oxy-nitride, oxy-carbide or carbo-nitride resulting in a final product with an attractive decorative colour of the surface. The subsequent processing as described here can be performed on the coated strip material in a continuous roll-to-roll process, or on components manufactured from the coated strip product. In the latter case the second step, e g the heat-treatment, is performed as a piece by piece process.

The final product in the form of a coated strip material in accordance with the present invention should also be capable of being readily manufactured to components suitable for applications as described above, in a cost-efficient and productive manufacturing process, including forming steps such as deep-drawing, punching, stamping, or the like. [cf. FIGS. 1 and 2]

### Description of the Decorative Surface Finish

Colour is the way the HVS (the human visual system) measures a part of the electromagnetic spectrum, approximately between the wave-lengths 300-830 nm. Because of certain properties of the HVS we are not able to see all of the possible combinations of the visible spectrum but we tend to group various spectra into colours. A colour space is a notation by which we can specify colours i.e. the human precipitation of the visible electromagnetic spectrum.

CIE, the International Commission on Illumination-abbreviated as CIE from the its French title Commission Internationale d'Éclairage—is an organisation devoted to international co-operation and exchange of information among its members countries on all matters relating to science and art of lighting.

CIE standardised the XYZ values as tristimulus values that describe any colour that can be perceived by an average human observer. These primaries are nonreal, i.e. they cannot be realised by actual colour stimuli. This colour space is chosen in such a way that every perceptible visual stimulus be described with positive XYZ values. A very important attribute of the CIE XYZ colour space is that it is device independent.

The transformation from CIE XYZ to CIE Lab is performed with following equations

$${L}^{*} = 116 {( \frac{Y}{Yn} )}^{\frac{1}{3}} - 16$$

$${a}^{*} = 500 [ {( \frac{X}{Xn} )}^{\frac{1}{3}} - {( \frac{Y}{Yn} )}^{\frac{1}{3}} ]$$

$${b}^{*} = 200 [ {( \frac{Y}{Yn} )}^{\frac{1}{3}} - {( \frac{Z}{Zn} )}^{\frac{1}{3}} ]$$

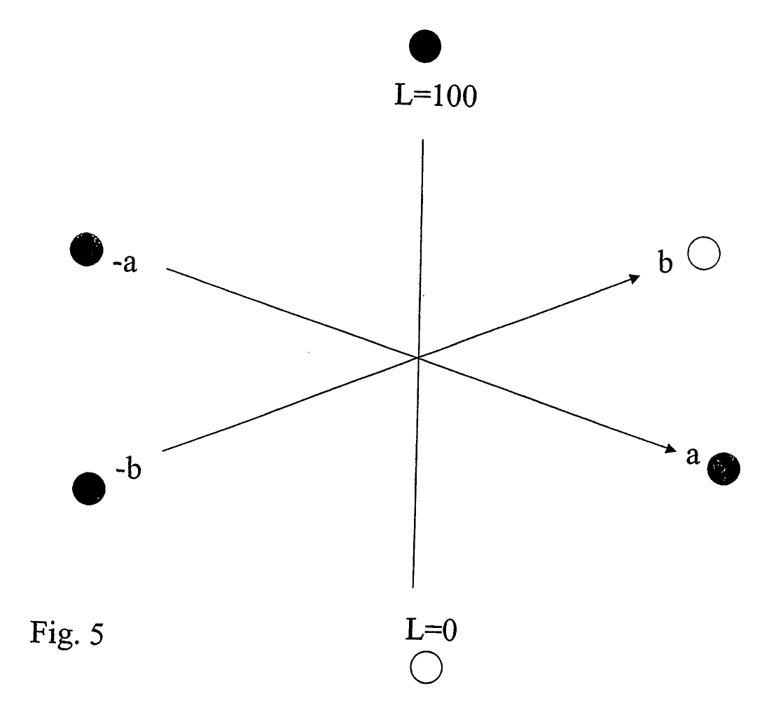

The trimulus values Xn, Yn, Zn are those of the normally white objective-colours stimulus. The L* value is the brightness from black to white, the a* value goes from green to red and the b* value is blue to yellow, see also FIG. 5.

The perceptually linear colour difference formulas between two colours is defined as:
ΔE={square root over (((ΔL)+(Δa)+(Δb)²))}

The colour can be describe in L*, a* and b* value.

The decorative coatings in the present invention is suitable for a colour space in following parameter of L*, a* and b*. The parameter of L*, a* and b* are usually 0<L*<95, −66<a*<64 and −90<b*<70. A blue colour is normally 20<L*<95, −66<a*<64 and −83<b*<0. A green colour is normally 20<L*<95, −66<a*<0 and −83<b*<70. A red colour is normally 20<L*<95, 0<a*<64 and −40<b*<35. A golden colour is normally 20<L*<95, −66<a*<64 and 0<b*<70. A black colour is normally 0<L*<50, −20<a*<20 and −20<b*<−20. A violet colour is normally 20<L*<95, 20<a*<60 and −25<b*<−60.

A blue colour is preferably 20<L*<50, −15<a*<50 and −70<b*<0. A green colour is preferably 60<L*<90, −60<a*<−7 and −83<b*<70. A red colour is preferably 40<L*<60, 20<a*<40 and −10<b*<10. A golden colour is preferably 60<L*<95, −10<a*<25 and 30<b*<50. A black colour is preferably 0<L*<40, −10<a*<10 and −10<b*<10. A violet colour is preferably 20<L*<50, 20<a*<60 and −25<b*<−60.

The method described in the present invention is especially suitable to use when a good consistency in the colour is desired.

### Description of the Substrate Material to be Coated

The material to be coated should have a good basic corrosion resistance, preferably with a chromium content of more than 12%, or at least 11% or minimum 10% (by weight), depending on the composition of the other alloying elements. It should also be possible to use in a state of good formability, which in a soft-annealed condition may be expressed in terms of elongation measured as A50 of more than 1%, normally more than 2%, and preferably more than 3%. Materials that are suitable to use are alloys such as ferritic chromium steels of the type AISI 400-series, austenitic stainless steels of the type AISI 300-series, hardenable chromium steels, duplex stainless steels, or precipitation hardenable stainless steels, such as the alloy disclosed in WO 93/07303. This means usually a composition of essentially (wt %):
Ferritic stainless steel, or an Austenitic stainless steel, or a duplex stainless steel of: 0,001-0,7% C, 10-26% Cr, 0,01-8% Mn, 0,01-2% Si, 0,001-16% Ni, up to 6% Mo, 0,001-0,5% N, up to 1,5% Al, up to 2% Cu, Nb+W+V in total up to 1% and rest essentially Fe, or:
Hardenable chromium steels of 0,1-1,5% C, 10-16% Cr, 0,001-1% Ni, 0,01-1,5% Mn, 0,01-1,5% Si, up to 3% Mo, 0,001-0,5% N, Nb+W+V in total up to 1% and rest essentially Fe; or
Precipitation hardenable steels of: 0,001-0,3% C, 10-16% Cr, 4-12% Ni, 0,1-1,5% Ti, 0,01-1,0% Al, 0,01-6% Mo, 0,001-4% Cu, 0,001-0,3% N, 0,01-1,5% Mn, 0,01-1,5% Si, Nb+W+V+Ta in total up to 2%, rest essentially Fe.

Also other stainless grades such as Cobalt alloyed steels, high-Ni alloys or Ni-based alloys may also be used. The substrate material can also be in different conditions, depending on the requirement of mechanical properties, such as in soft annealed or cold-rolled condition or even hardened condition. The substrate material should in soft-annealed condition have a tensile strength of maximum 1400 MPa, preferably max 1000 MPa, in order to have a good formability. In cold-rolled condition should the substrate material have a tensile strength of minimum 500 MPa, normally min 700 MPa and preferably min 1000 MPa, and in hardened condition a minimum tensile strength of usually 1000 MPa, or more normally min 1200 MPa. The coating method may be applied on any kind of product made of said type of stainless steel alloys and in the form of strip, bar, wire, tube, foil, fiber etc., preferably in the form of strip or foil, that have good hot workability and also can be cold-rolled to thin dimensions. The alloy should also readily be manufactured to components in a productive manufacturing process including steps such as forming, deep drawing, punching, stamping, or the like.

The thickness of the strip substrate material is usually between 0,015 mm to 3,0 mm and suitably between 0,03 mm to 2 mm. Preferably; it is between 0,03 to 1,5 mm, and even more preferably between 0,03 to 1 mm. The width of the substrate material depends on if the coating is made before or after any foreseen slitting operation. Further, said width should preferably be selected to be a width suitable for further manufacturing to the final width of the component intended to be used in a consumer related application. In principle, the width of the substrate material is therefore between 1 to 1500 mm, suitably 1 to 1000 mm, or preferably 1 to 500 mm, or even more preferably between 5 and 500 mm. The length of the substrate material is suitably at least 10 m, normally between 50 and 20 000 m and preferably between 100 and 20 000 m. According to an embodiment the substrate material is at least 500 m long.

### Description of the Coating Method

A variety of physical or chemical evaporation deposition methods for the application of the coating media and the coating process may be used as long as they provide a continuous uniform and adherent layer. As exemplary of deposition methods can be mentioned chemical vapor deposition (CVD), metal organic chemical vapor deposition (MOCVD), physical vapor deposition (PVD) such as sputtering and evaporation by resistive heating, by electron beam, by induction, by arc resistance or by laser deposition methods, but for the present invention especially two PVD methods are preferred for the deposition, either electron beam evaporation (EB) or sputtering. Optionally, the EB evaporation can be plasma activated to even further ensure good quality coatings of dense and decorative layers.

For the present invention, it is a pre-requisite that the coating method is integrated in a roll-to-roll strip production line with a minimum strip speed of 3 m/min to achieve a cost efficient productivity and also to be able to maintain the properties of the substrate material by minimizing the heat influence, which otherwise would risk to deteriorate the properties of the end-product. The coating layer is then deposited by means of electron beam evaporation (EB) or by sputtering in a roll-to-roll process. If multi layers are needed; the formation of them can be achieved by integrating several EB deposition chambers or sputtering chambers in-line. The deposition of metallic coatings should be made under reduced atmosphere at a maximum pressure of 1×10⁻² mbar with no addition of any reactive gas to ensure essentially pure metal films. The deposition of metal oxides should be performed under reduced pressure with an addition of an oxygen source as reactive gas in the chamber. A partial pressure of oxygen should be in the range 1-100×10⁻⁴ mbar. If other types of coatings are to be achieved, e.g., metal carbides and/or nitrides such as TiN, TiC or CrN, or mixtures thereof the conditions during the coating should be adjusted with regard to the partial pressure of a reactive gas so as to enable the formation of the intended compound. In the case of oxygen, a reactive gas such as H₂O, O₂ or O₃, but preferably O₂, may be used. In the case of nitrogen a reactive gas such as N₂, NH₃ or N₂H₄, but preferably N₂, may be used. In the case of carbon, any carbon containing gas may be used as reactive gas, for an example CH₄, C₂H₂ or C₂H₄. All these reactive EB evaporation processes may be plasma activated.

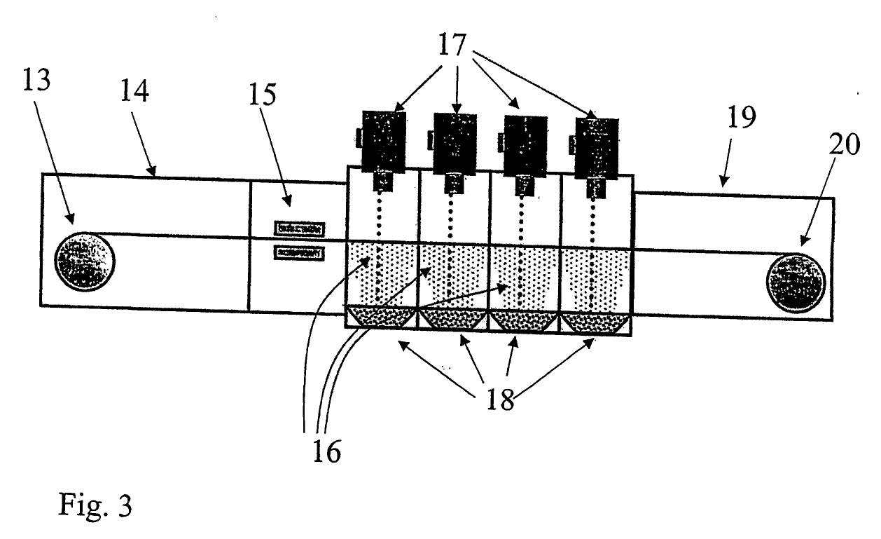

To enable a good adhesion, different types of cleaning steps are used. First of all, the surface of the substrate material should be cleaned in a proper way to remove all oil residues, which otherwise may negatively affect the efficiency of the coating process and the adhesion and quality of the coating layer. Moreover, the very thin native oxide layer that normally always is present on a steel surface must be removed. This can preferably be done by including a pre-treatment of the surface before the deposition of the coating. In this roll-to-roll production line, the first production step is therefore preferably an ion assisted etching of the metallic strip surface to achieve good adhesion of the first covering layer [see FIG. 3].

### DESCRIPTION OF EMBODIMENTS OF THE INVENTION

Six examples of embodiments of the invention will now be described in more detail.

Firstly, the substrate materials are produced by ordinary metallurgical steel making to a chemical composition as described in the specific examples. They are afterwards hot-rolled down to an intermediate size, and thereafter cold-rolled in a conventional manner in several steps with a number of recrystallization steps between said rolling steps, until a final specific thickness of normally <3 mm, and a width of maximum 400 mm. The surface of the substrate material is then cleaned in a proper way to remove oil residuals from the rolling. Thereafter, the coating process takes place in a continuous process line, starting with decoiling equipment. The first step in the roll-to-roll process line can be a vacuum chamber or an entrance vacuum lock followed by an etch chamber, in which ion-assisted etching takes place in order to remove the thin oxide layer on the surface of the stainless substrate material. The strip then enters into the E-beam evaporation chamber(s) or sputtering chamber(s) in which the deposition takes place. A layer of normally 0,01 up to 10 μm is deposited in a ratio between the thickness of the coating and the thickness of the strip to be up to max 7%, the preferred thickness depending on the application. In the six examples described here, the specific thickness of the layer is deposited by using one E-beam evaporation chamber and/or one sputtering chamber.

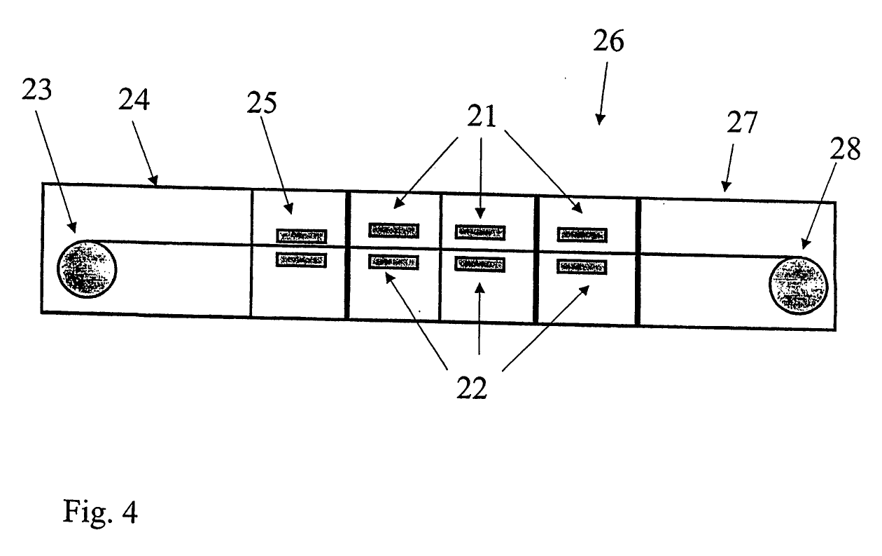

The roll-to-roll PVD process referred to above is illustrated in FIG. 3-4. In FIG. 3 as an embodiment of the present invention the deposition method is electron beam evaporation and the first part of such a production line is the uncoiler 13 within a vacuum chamber 14, then the in-line ion assisted etching chamber 15, followed by a series of EB evaporation chambers 16, the number of EB evaporation chambers needed can vary from 1 up to 10 chambers, this to achieve a multi-layered structure, if so desired. All the EB evaporation chambers 16 are equipped with EB guns 17 and water-cooled copper crucibles 18 for the evaporation. After these chambers come the exit vacuum chamber 19 and the recoiler 20 for the coated strip material, the recoiler being located within vacuum chamber 19. The vacuum chambers 14 and 19 may also be replaced by an entrance vacuum lock system and an exit vacuum lock system, respectively. In the latter case, the uncoiler 13 and the coiler 20 are placed in the open air. After the EB evaporation, the coated strip material passes through the exit vacuum chamber or exit vacuum lock before it is being coiled on to a coiler. In FIG. 4 as a further embodiment to the present invention the deposition method is sputtering and the first part of such a production line is the uncoiler 23 within a vacuum chamber 24, then the in-line ion assisted etching chamber 25, followed by a series of sputtering chambers 21, the number of sputtering chambers needed can vary from 1 up to 10 chambers, this to achieve a multi-layered structure, if so desired. All the sputtering chambers 21 are equipped with dual magnetrons 22 for the deposition. After these chambers comes the exit vacuum chamber 27 and the recoiler 28 for the coated strip material, the recoiler being located within vacuum chamber 27. The vacuum chambers 24 and 27 may also be replaced by an entrance vacuum lock system and an exit vacuum lock system, respectively. In the latter case, the uncoiler 23 and the coiler 28 are placed in the open air. After the sputtering, the coated strip material passes through the exit vacuum chamber or exit vacuum lock before it is being coiled on to a coiler.

As an even further embodiment to the present invention, the deposition method is both electron beam evaporation chambers 16 and sputtering chambers 21 integrated in a series of deposition chambers in a similar production process as described in FIGS. 3 and 4.

The coated strip material can now, if needed, be further processed by, for example, annealing, rolling or slitting, to obtain the preferred final dimension and condition for the manufacturing of components.

The final product as described in the six examples, i.e., a coated stainless strip material in the specific strip thickness and with a thin covering coating layer in accordance to the examples described below, have a very good adhesion of the coated layer and are thus suitable to be used in a cost-efficient and productive manufacturing of components in consumer related applications. The good adhesion of the layers is further described in FIGS. 1-2. A substrate material of a stainless steel strip 1 that has been coated with a thin covering layer 2 so as to produce a coated strip product in accordance with the present invention, is put on to a support 4 with a shaped top that has a radius 5 that is maximally 5*t, where t is the thickness 3 of said strip. A bend test is then performed in a way that bends said strip up to 180° over the radius 5 and the bending continues until the selected bend angle is attained, and for a bend-angle of 180° until the strip ends meet 6. The substrate material is normally in soft-annealed condition during a bend-test for testing of the adhesion of the coating, since it is the adhesion that is to be tested and not the basic formability of the substrate material. Therefore, the test is performed with the coated strip material in a state in which the limitation of formability is in the coating and not in the substrate material. When the bending has been completed in such a bend test, the test specimen is investigated and especially the quality of the layer after bending 7 and the quality of the substrate after bending 8 and the adhesion between said layer and substrate. The test specimens in accordance with the six examples here have all been tested and the results can be seen in Table 1. The different examples in the form of a coated strip test specimen have been tested in a bend-test as described in FIG. 1-2 in a bend angle of between 90° and 180°. Afterwards all tested specimens have been inspected visually with regard to if any tendency of flaking, cracking of the layer, or the like, can be seen. Also, all test-specimens tested in a bend-angle of 180° have been investigated with regard to adhesion with an adhesive Scotch tape, and inspected afterwards if any flakes coming from the coated layer can be seen on the tape. A coated strip material as tested according to this description should have such a good adhesion of the layer that a radius of maximum 5*t, usually 3*t, normally 2*t, preferably 1,5*t, and even more preferably 1*t, can be used without any tendency to flaking of the layer or the like. As can be seen in Table 1, the different examples described here, do not show any tendency at all to any flaking, or the like. All bend-tested samples passed the test with the ranking “accepted”.

The six examples will now be described more in detail regarding their respective specifics:

### EXAMPLE 1

A 0,280 mm thick AISI 304 substrate material in a nominal composition of max 0,08% C, max 1% Si, max 2% Mn, 18.0-20.0% Cr, 8.0-10.0% Ni and rest essentially Fe, and in annealed condition coated by using a strip speed of about 10 m/min with electron beam evaporation, with about 1 um TiO directly on the substrate to get a bronze colour. The coated specimen with the TiO layer passed the bending test and also the scotch tape test. See sample 1 in Table 1 for the bending test result, scotch tape test and the measured L*, a* and b* colour values.

### EXAMPLE 2

A 0,317 mm thick AISI 304 substrate material in a nominal composition of max 0,08% C, max 1% Si, max 2% Mn, 18.0-20.0% Cr, 8.0-10.0% Ni and rest essentially Fe, and in cold rolled condition coated using a strip speed of minimum 3 m/min by sputtering with TiN, TiAlN in several step to get multilayered structures. The multilayered coated material gets colours of blue, green and violet. The total layer thickness is 45 nm for the blue strip, 50 nm for the purple strip and 100 nm for the green strip. The specimens with the coloured layers all passed the bending test and also the scotch tape tests. See samples 2-4 table 1 for the bending test result, scotch tape test and the measured L*, a* and b* colour values.

### EXAMPLE 3

A 0,317 mm thick AISI 304 substrate material in a nominal composition of max 0,08% C, max 1% Si, max 2% Mn, 18.0-20.0% Cr, 8.0-10.0% Ni and rest is essentially Fe, in cold rolled condition coated by using a strip speed of minimum 3 m/min by sputtering with TiAlN to get a black colour. The coated specimen with the black layer passed the bending test and also the scotch tape test. See sample 5 in Table 1 for the bending test result, scotch tape test and for the measured L*, a* and b* colour values.

### EXAMPLE 4

A 0,137 mm thick substrate material with the designation Sandvik 13C26 with a nominal composition of 0,7% C, 13% Cr, 0,4% Si and 0,7% Mn (by weight) and rest essentially Fe, coated with TiN directly on to the steel by a sputtering process using a strip speed of minimum 3 m/min. The layer was coloured in gold. The sample was afterwards heat-treated in 1100° C. for 10s under N₂/H₂ atmosphere, which is a normal hardening procedure for this type of steel. See samples 6-7 in Table 1 for the bending test result, scotch tape test and for the measured L*, a* and b* colour values. The difference in colour between the gold coloured specimen before the heat-treatment and after the heat-treatment is measured to be ΔE=6,5

### EXAMPLE 5

A 0,1 mm thick substrate material with the designation Sandvik 13C26 with a nominal composition of 0,7% C, 13% Cr, 0,4% Si and 0,7% Mn (by weight)and rest essentially Fe coated using a strip speed of about 10 m/min by electron beam evaporation with about 0,1 μm titanium dioxide directly on the substrate to get a light turquoise colour. The specimen with the TiO₂ layer passed the scotch tape test. See sample 8 in Table 1 for the bending test result, scotch tape test and for the measured L*, a* and b* colour values.

### EXAMPLE 6

A 0,1 mm thick substrate material with the designation Sandvik 13C26 with a nominal composition of 0,7% C, 13% Cr, 0,4% Si and 0,7% Mn (by weight)and rest essentially Fe coated using a strip speed of minimum 3 m/min by electron beam evaporation with Cr₂O₃ directly on a previously TiN-coated substrate to get a black colour. The specimen with the Cr₂O₃ layer passed the bending test and also the scotch tape test. See sample 9 in Table 1 for the bending test results, scotch tape test results and the measured L*, a* and b* colour values.

1. A coated stainless steel strip product with an evenly distributed layer on one side or both sides of said strip, wherein said layer has a decorative appearance, the thickness of said layer is maximally 10 μm, the tolerance of said layer is maximally +/−30% of the layer thickness, the parameter value of L*, a*, b* is respectively 0<L*<95, −66<a*<64, −90<b*<70, the tolerance of said decorative appearance as expressed in terms of ΔE is maximally 15 and that the layer has such a good adhesion so that the coated steel strip when tested in soft-annealed condition can be bent more than 90° over a radius maximally equal to 5*t, where t is the thickness of said strip, without showing any tendency to flaking or the like.

2. Product according to claim 1, wherein the thickness of the strip substrate is between 0.015 mm and 3.0 mm.

3. Product according to claim 1, wherein the ratio between the thickness of the coating and the thickness of the strip is max 7%.

4. Product according to claim 1, wherein it is made of a substrate of ferritic stainless steel, austenitic stainless steel, stainless spring steel, duplex stainless steel, hardenable chromium steel or precipitation hardenable stainless steel.

5. Product according to claim 1, wherein the substrate material in soft-annealed condition has a tensile strength of maximum 1400 MPa.

6. Product according to claim 1, wherein the substrate material in cold-rolled condition has a tensile strength of minimum 500 MPa.

7. Product according to claim 1, wherein the substrate material in hardened and/or tempered condition has a tensile strength of minimum 1000 MPa.

8. Product according to claim 1, wherein the coating is a binary metal oxide or a ternary metal oxide or mixtures or solid solutions of said binary metal oxides, the main ingredient in such a mixture or solid solution being Al₂O₃, TiO₂ or Cr₂O₃.

9. Product according to claim 1, wherein the coating is a coating of metal carbides or metal nitrides, or mixtures thereof.

10. Product according to claim 9 subsequently heat-treated in a tempering or a hardening process using a suitable gas atmosphere, wherein the difference of the decorative appearance of the coating after the heat-treatment compared to before the heat-treatment as expressed in terms of ΔE is maximally 15.

11. Product according to claim 10, wherein the material after the subsequent heat-treatment has a tensile strength of more than 1000 MPa.

12. Product according to claim 1, wherein the layer has a multi-layer constitution of up to 10 layers.

13. Product according to claim 12, wherein each individual layer has a thickness of between 0.01 to 10 μm.

14. Product according to claim 13, wherein the layer has a multi-layer constitution of individual layers of different coatings of nitrides or carbides or mixtures thereof.

15. Product according to claim 14, wherein there is also at least one covering layer of nickel or chromium or aluminum or titanium in thickness up to 2 μm.

16. Product according to claim 1 with a desired decorative appearance achieved by using a two-step method comprising a coating applied in a first step and a sub-sequent processing done in a second step to achieve a desired color, wherein the coating in the first step is a suitable covering layer of a metal or a binary oxide of said metal or mixtures of said metal and said binary oxide.

17. Product according to claim 16, wherein the material after the subsequent processing in the second-step has a tensile strength of more than 1000 MPa.

18. Product according to claim 16, wherein the desired color is achieved by incorporating a suitable element into the coating applied in the first step, by using a reactive gas during a suitable heat-treatment.

19. Product according to claim 16, wherein the final product after the second step has a coating with a desired color consisting of metal oxide, metal nitride, metal carbide, or a mixture.

20. Product according to claim 16, wherein the layer has a multi-layer constitution of up to 10 layers.

21. Product according to claim 16, wherein each individual layer has a thickness of between 0.01 to 10 μm.

22. Product according to claim 1, wherein a decorative appearance is of a blue color of normally 20<L*<95, −66<a*<64 and −83<b*<0.

23. Product according to claim 1, wherein a decorative appearance is of a green color of normally 20<L*<95, −66<a*<0 and −83<b*<70.

24. Product according to claim 1, wherein a decorative appearance is of a red color of normally 20<L*<95, 0<a*<64 and −40<b*<35.

25. Product according to claim 1, wherein a decorative appearance is of a golden color of normally 20<L*<95, −66<a*<64 and 0<b*<70.

26. Product according to claim 1, wherein a decorative appearance is of a black color of 0<L*<50, −20<a*<20 and −20<b*<20.

27. Product according to claim 1 wherein a decorative appearance of a typical violet color of normally 20<L*<95, 20<a*<60 and −25<b*<−60.

28. A product according to claim 1, wherein the product is incorporated into outdoor life applications, sports and sea-life applications, household applications, camera applications, mobile phones and other telecom applications, edge applications, and applications for personal belongings and care.

29. Method of manufacturing a coated stainless steel strip product according to claim 1, wherein said product is produced in a continuous roll-to-roll process with a minimum strip speed of 3 m/min, included in a strip production line using sputtering and/or electron beam evaporation comprising an etch chamber in-line.

30. Product according to claim 14, wherein nitrides are TiN and carbides are

31. Product according to claim 14, wherein the multi-layer constitution includes layers of oxides in the form of Cr₂O₃ or Al₂O₃ or TiO₂,

32. Product according to claim 16, wherein the metal includes aluminum, chromium, titanium, zirconium and wherein the binary oxide of said metal includes Al₂O₃, TiO₂, Cr₂O₃,

33. Product according to claim 18, wherein the suitable element is oxygen, carbon, nitrogen.

34. Product according to claim 19, wherein the mixture includes metal oxy-nitride, metal oxy-carbide or metal carbo-nitride.

35. Product according to claim 28, wherein edge applications include a knife, a saw and a shaving application.

36. Product according to claim 28, wherein applications for personal belongings and care include watches, glasses, cosmetic applications, buttons and zippers in clothing, and perfume bottles.

37. A coated stainless steel strip product, comprising:
a strip substrate; and
an evenly distributed layer on one side or both sides of a strip substrate,
wherein said layer includes a decorative appearance,
wherein a thickness of said layer is maximally 10 μm,
wherein a tolerance of said layer is maximally +/−30% of the layer thickness,
wherein said product has a color represented by parameter values L*, a*, b*, of 0<L*<95, −66<a*<64, −90<b*<70, where L* is the brightness from black to white, a* is the brightness form green to red, and b* is the brightness from blue to yellow, and
wherein the coated strip product, in a soft-annealed condition, is bent more than 90° over a radius maximally equal to 5*t without flaking, where t is a thickness of the strip substrate.

38. The product of claim 37, wherein a difference in the color before a heat treatment and after the heat treatment is represented by ΔE, and wherein ΔE is maximally 15 for a strip substrate width of 400 mm.
